(19) United States
(12) Patent Application Publication
(10) Pub. No.: US 2011/0073946 A1
(43) Pub. Date: Mar. 31, 2011

(54) LDMOS TRANSISTOR

(75) Inventors: Stephan J. C. H. Theeuwen, Nijmegen (NL); Henk J. Peuscher, Wijchen (NL); Rene Van Den Heuvel, Beuningen (NL); Paul Bron, Grave (NL)

(73) Assignee: NXP B.V., Eindhoven (NL)

(21) Appl. No.: 12/994,602

(22) PCT Filed: May 19, 2009
(86) PCT No.: PCT/IB2009/052082

§ 371 Date: Nov. 24, 2010

(30) Foreign Application Priority Data
May 26, 2008 (EP) 08156923.8

(51) Int. Cl. H01L 29/78; H01L 21/336

(52) U.S. Cl. 257/344; 438/308; 257/E21.435; 257/E29.266

(57) ABSTRACT

An LDMOS transistor (100) on a substrate (70a, 70b) of a first conductivity type, comprises a source region (10) with a source portion (73) and a drain region (12). The source portion and drain region are of a second conductivity type opposite to the first conductivity type and are mutually connected through a channel region (28) in the substrate over which a gate electrode (14) extends. The drain region comprises a drain contact region (16) and a drain extension region (15) which extends from the channel region (28) towards the drain contact region. The drain contact region is electrically connected to a top metal layer (22) by a drain contact (20), and a poly-Si drain contact layer (80) is arranged as a first contact material in between the drain contact region and the drain contact in a contact opening (51) of a first dielectric layer (52) deposited on the surface of the drain region. The poly-Si drain contact layer comprises a dopant element of the second conductivity type which is diffused therefrom through annealing to form said drain contact region.

### FIELD OF THE INVENTION

This invention relates to an LDMOS transistor. Also, the invention relates to a semiconductor device comprising such an LDMOS transistor. Moreover, the invention relates to a method of manufacturing an LDMOS transistor.

### BACKGROUND OF THE INVENTION

In base stations for personal communications systems (GSM, EDGE, W-CDMA), RF power amplifiers are the key components. For these power amplifiers, RF Laterally Diffused Metal Oxide Semiconductor, generally abbreviated as LDMOS, transistors are now the preferred choice of technology, because of their excellent high power capabilities, gain and linearity.

To meet the demands imposed by new communication standards, the performance of LDMOS is subject to continuous improvements. Wideband CDMA (W-CDMA) requires linear operation of the LDMOS power amplifier, which means operating the LDMOS power amplifier sufficiently far in back off reducing at the same time the efficiency of the power amplifier. Nowadays much attention is paid to improve this trade-off between linearity and efficiency on device and system level. The continuous improvements made in LDMOS technology have led to a present 32 percent W-CDMA efficiency world-record value, and the future prospects to increase the performance even further.

The performance boost has been primarily accomplished by a rigorous reduction of output losses of the LDMOS transistor. The dominant loss mechanisms for the LDMOS transistor are series and parallel losses. Series losses are due to the ON-resistance, which is determined by the drain-extension and is frequency independent. Parallel losses are due to loss in the output capacitance where the resistive part is a combination of resistance of the drain-extension and substrate resistance.

In WO 2007/017083 an LDMOS transistor is disclosed, which comprises a source and a drain region in a semiconductor substrate of first conductivity type (e.g., p type), both source and drain region being of a second conductivity type (e.g., n type) and being mutually connected through a channel region over which a gate electrode extends. The drain region comprises a drain contact region and a drain extension region extending from the channel region towards the drain contact region. Typically, the drain contact region is highly doped, while the drain extension region is relatively low doped.

The drain contact region is electrically connected to a top metal layer via a drain contact.

The connection between the drain contact and the top metal layer may extend over at least one intermediate metallisation level comprising at least one intermediate metal layer and at least one inter-metal contact.

The drain contact is connected to the drain contact region by a silicided area acting as drain silicide region.

A reduction in drain-width to reduce the output capacitance of the LDMOS transistor (i.e., the capacitance between the drain contact region and the substrate) has been the main driver for efficiency improvement during recent development of state-of-art RF-LDMOS transistor technology for base-stations.

However, to improve the electrical properties of the LDMOS transistor of the prior art, it is no longer feasible to follow this scheme of reduction of the drain-width for a number of reasons, e.g.:
A highly doped n+ implantation for forming the drain contact region in the drain region is not achievable in a more narrow region, due to contradictory requirements of resist thickness and lithographic dimensions (laterally, along the surface of the substrate). For a more narrow region with a smaller width the opening in a resist layer during lithographic processing becomes smaller while the thickness of the resist layer also reduces. At the same time the implantation process of an ion beam through the opening in the resist layer becomes less efficient, i.e. the resist does no longer block the high dope implant.
A drain silicide region between the drain contact region and the drain contact has to be inside the boundaries of the highly doped n+ region (drain contact region) to prevent an increase in leakage currents (a so-called soft breakdown) which results in more strict lithographic requirements, since the lateral opening in the resist layer for defining the drain silicide region has to be smaller than the lateral opening for the drain contact.
The contact opening for defining the drain contact on top of the drain silicide region again has to lie within the drain silicide region. This requirement for drain contact lithography dimensions gets too critical for standard lithography and would require a lithographic processing with a higher resolution. Typically, in LDMOS transistors of the prior art the minimal feature size is in the order of 400-600 nm, which allows manufacturing using relatively simple lithography such as C75-C35. A reduction of the minimal feature size to lower values would require a more sophisticated lithography.

### SUMMARY OF THE INVENTION

It is an object of the present invention to improve the electrical properties of the LDMOS transistor, more in particular the reduction of the output capacitance of the LDMOS transistor while the difficulties of the lithographic processing are overcome, and one or more of the above mentioned problems.

According to the invention, this object is achieved by providing an LDMOS transistor on a substrate of a first conductivity type, comprising a source region and a drain region; the source and drain regions being of a second conductivity type opposite to the first conductivity type and being mutually connected through a channel region in the substrate over which a gate electrode extends; the drain region comprising a drain contact region and a drain extension region which extends from the channel region towards the drain contact region, the drain contact region being electrically connected to a top metal layer by a drain contact; a poly-Si drain contact layer being arranged as a first contact material in between the drain contact region and the drain contact and in a contact opening of a first dielectric layer being deposited on the surface of the drain region, the poly-Si drain contact layer comprising a dopant element of the second conductivity type.

Advantageously, the present invention allows to selectively dope the drain contact region from the poly-Si drain contact layer by means of an outdiffusion during an annealing stage of the manufacturing process. The selective doping can be performed at a smaller scale than can be achieved by an ion implantation process. As a result the construction of a poly-Si drain contact provides a reduction of the intrinsic drain-source capacitance which advantageously results in a high transistor efficiency, i.e., the effective output power during use can increase.

Moreover, the poly-Si drain contact can be constructed using a substantially identical lithographical processing scheme without the need for exceeding critical dimensions of such a scheme.

In an embodiment, the poly-Si drain contact layer comprises a lower poly-Si layer and an upper silicide layer, the lower poly-Si layer being in contact with the drain contact region, the upper silicide layer being in contact with the drain contact.

Advantageously, the application of the poly-Si drain contact between the silicide layer and the drain region overcomes leakage problems due to soft breakdown.

In an embodiment, the poly-Si drain contact layer has an extending portion which extends over the first dielectric layer.

Advantageously, the overlap of the poly-Si drain contact layer allows to relax the lithographic requirements for contacting the drain contact region to the drain contact.

In an embodiment, the extending portion of the poly-Si drain contact layer over the first dielectric layer is arranged as a field plate adapted in use for tailoring an electric field at an edge of the drain contact region. Advantageously, the use as field plate allows to improve the breakdown voltage of the transistor.

Also, the invention relates to a method of manufacturing an LDMOS transistor comprising:
providing a substrate of a first conductivity type; forming in the substrate a source region and a drain region, the source and drain regions being of a second conductivity type opposite to the first conductivity type and being mutually connected through a channel region in the substrate; depositing a first dielectric layer over at least the drain region; patterning the first dielectric layer to create a contact opening at a location of the drain region where a drain contact region is to be created; depositing and subsequently patterning a poly-Si layer to form a poly-Si drain contact layer in the contact opening in the first dielectric layer as a first contact material on the drain contact region, the poly-Si drain contact layer comprising a dopant element of the second conductivity type.

### BRIEF DESCRIPTION OF DRAWINGS

The invention will be explained in more detail below with reference to a few drawings in which illustrative embodiments of the invention are shown. It will be appreciated by the person skilled in the art that other alternative and equivalent embodiments of the invention can be conceived and reduced to practice without departing from the true spirit of the invention, the scope of the invention being limited only by the appended claims.

FIG. 1 shows a cross-sectional view of an LDMOS transistor design from the prior art;

FIG. 2 shows a first cross-sectional view of an LDMOS transistor design according to an embodiment of the present invention,

FIG. 3 shows a comparison of an output capacitance of an LDMOS transistor according to an embodiment and an LDMOS transistor of the prior art.

The Figures are not drawn to scale. In general, identical components are denoted by the same reference numerals in the Figures.

### DETAILED DESCRIPTION OF THE EMBODIMENTS

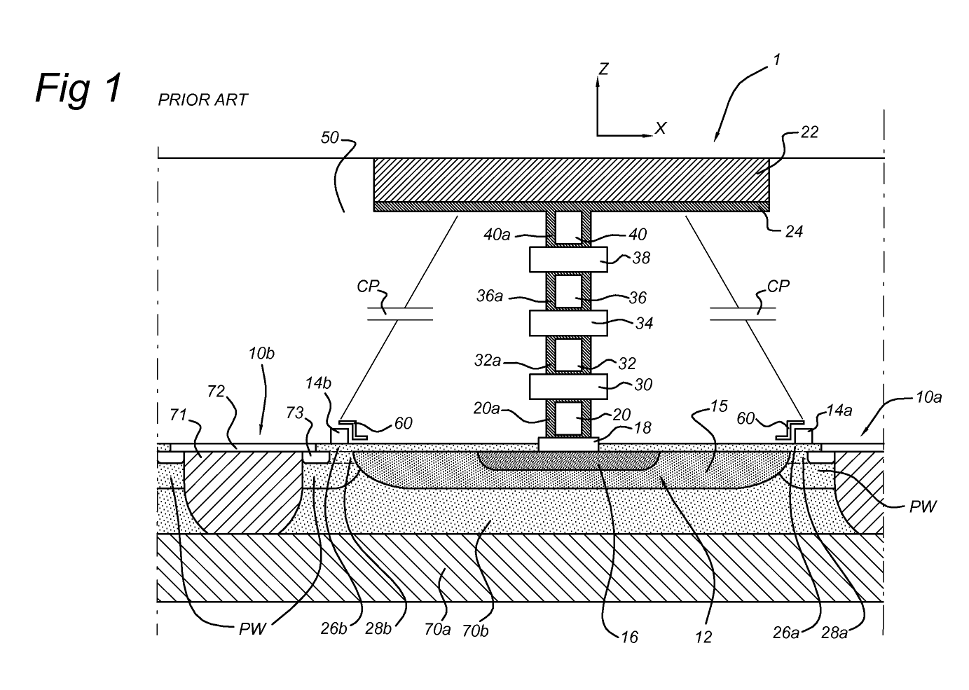

FIG. 1 shows a cross-sectional view of a design of an LDMOS transistor 1 from the prior art.

The LDMOS transistor 1 of the prior art is arranged on a substrate 70a, 70b and comprises first and second source regions 10a, 10b, and a common drain region 12. The substrate 70a, 70b comprises a highly doped semiconductor substrate layer 70a of a first conductivity type (e.g., p-type). On top of the highly doped semiconductor substrate 70a an epitaxial Si layer 70b is arranged. The source and drain regions 10a, 10b, 12 are of a second conductivity type opposite to the first conductivity type (e.g., n-type). The first source region 10a and the common drain region are mutually connected through a first channel region 28a over which a gate electrode 14a extends. The gate electrode 14a is separated from the first channel region 28a by a gate oxide 26a. The second source region 10b and the common drain region are mutually connected through a second channel region 28b over which a second gate electrode 14b extends. The gate electrode 14b is separated from the second channel region 28b by the gate oxide 26b.

The source region 10a, 10b is in connection with the highly doped semiconductor substrate layer 70a. The substrate region is contacted with a highly doped sinker 71a, 71b of the first conductivity type, which is in contact via a silicide or metal layer 72a, 72b to a doped source portion of second conductivity type 73a, 73b. The doped source portion 73a, 73b of second conductivity type is arranged between the channel region 28a, 28b and the sinker 71a, 71b. The doped source portion of the second conductivity type is embedded in a well region PW of the first conductivity type.

The common drain region 12 comprises a drain contact region 16 and a drain extension region 15 which extends from both the first channel region 28a and the second channel 28b towards the drain contact region 16. Typically, the drain contact region 16 is highly doped (n+), while the drain extension region is relatively low doped (n− or n).

The drain contact region 16 is electrically connected to a top metal layer 22 via a drain contact 20. The drain contact 20 is connected to the drain contact region 16 by a silicided area acting as drain silicide region 18. The drain contact 20 comprises a conducting body which is optionally embedded in a liner 20a.

The connection between the drain contact 20 and the top metal layer may extend over at least one intermediate metallisation level comprising at least one intermediate metal layer 30, 34, 38 and at least one inter-metal contact 32, 36, 40.

The at least one inter-metal contact 32; 36; 40 each comprises a conducting body optionally embedded in a respective liner 32a; 36a; 40a.

The connection between the drain contact 20 and the top metal layer is embedded in a dielectric layer 50. Between the dielectric layer 50 and the top metal layer a liner 24 may be arranged.

Each gate electrode 14a, 14b is arranged with a shield 60 to shield the gate electrode 14a, 14b from the top metal layer 22 and the connection between drain contact region and top metal layer.

WO2007069188 discloses a MOS transistor in which the shield comprises a multiple of portions extending over the drain extension region essentially parallel to a top surface of the drain extension region, in which a second distance between the drain extension region and a second portion of the shield layer is larger than a first distance between the drain extension region and a first portion of the shield layer, which first portion is closer to the gate electrode than the second portion of the shield layer.

The width of the LDMOS transistor (along horizontal direction X) is typically of the order of 5-10 μm. The LDMOS transistor extends in a direction orthogonal to the horizontal direction X and vertical direction Z over a length typically in the order of about 500 μm.

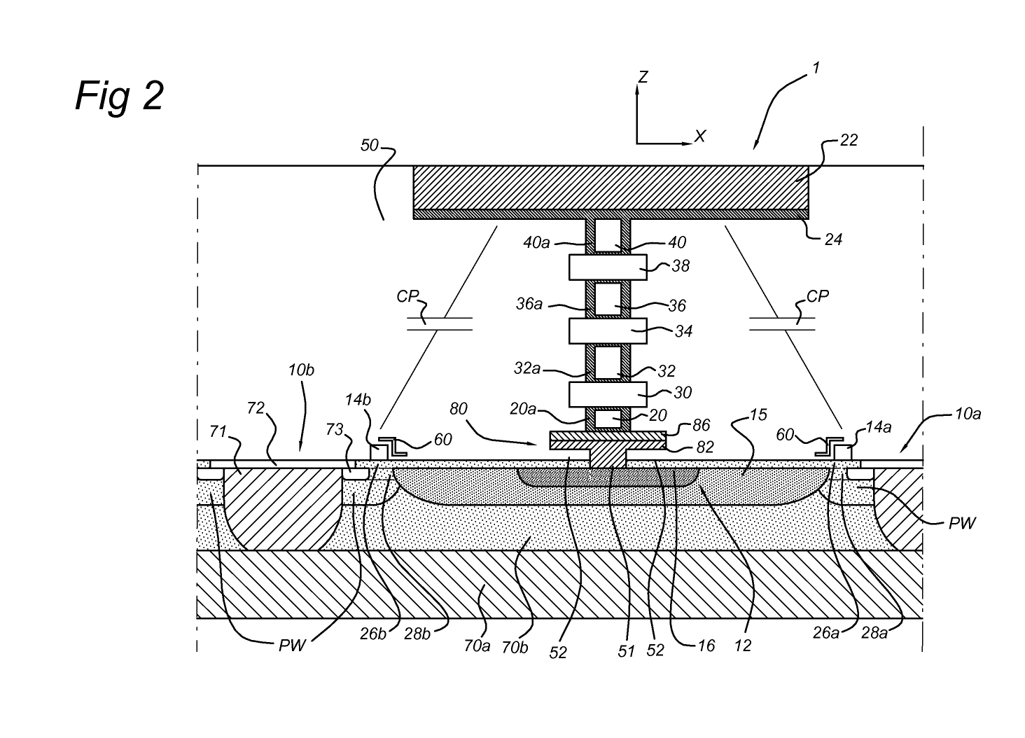

FIG. 2 shows a first cross-sectional view of an LDMOS transistor design 100 according to an embodiment of the present invention.

The present invention allows to reduce the output capacitance between drain contact region 16 and substrate 70a, 70b, without reduction of the feature size of the drain contact 20, by providing a poly-Si drain contact layer 80 as first contact material to a drain contact region 84.

The poly-Si drain contact layer 80 is provided in a contact opening 51 in a first dielectric layer 52. The contact opening 51 has substantially the same size as the drain contact. Advantageously, this allows to use basically the same lithographic processing as for the LDMOS transistor of FIG. 1.

The poly-Si drain contact layer 80 comprises a lower poly-Si layer 82 and an upper silicide layer 86, wherein the lower poly-Si layer 82 is in contact with a drain contact region 84 of the drain region 12. The upper silicide layer 86 is in contact with the drain contact 20.

In an embodiment, the poly-Si drain contact layer has an extending portion which extends over the first dielectric layer 52. Advantageously, the extending portion of the poly-Si drain contact layer 80 over the first dielectric layer provides a field plate with dimensions adapted for tailoring the electric field at the edge of the drain contact region during use of the LDMOS transistor 100.

To obtain compatibility with the processing method of the prior art for forming the drain contact, the extending portion of the lower poly-Si layer may have a substantially same width as the width of the drain silicide region 18 as applied in the LDMOS transistor of FIG. 1.

Below, the method of manufacturing of a LDMOS transistor comprising the poly-Si drain contact layer will be explained in more detail. Here, it is noted that the lower poly-Si layer 82 comprises a dopant element of the second conductivity type, which during manufacturing diffuses into the drain region and forms the highly doped drain contact region 84. By controlling the annealing temperature and time of the outdiffusion process is advantageously possible to control the dimension of the drain contact region to a size smaller than achievable by the ion implantation step of the prior art. The present invention allows to selectively dope the drain contact region 16 from the poly-Si drain contact layer by means of an outdiffusion during an annealing stage of the manufacturing process. The selective doping process can be performed at a smaller scale than can be achieved by an ion implantation process.

In an exemplary embodiment, the contact opening 51 in the first dielectric layer 52 has a width of about 400 nm, the width of the extending portion of the lower poly-Si layer 82 is about 800 nm and the width of the drain contact is about 400 nm. The lateral size in direction X of the highly doped drain contact region 82 is typically between about 400 and about 500 nm.

A method for manufacturing the LDMOS transistor of the present invention comprises the provision of a silicon wafer with a either highly or lowly doped semiconductor substrate layer 70a of the first conductivity type (e.g. p++ or p). Alternatively, the full silicon wafer may be highly doped to obtain conductivity according to the first conductivity type by a suitable dopant (for example Boron).

Next, an epitaxial layer 70b is deposited on the highly doped semiconductor substrate layer of the first conductivity type 70a.

After that, the source regions 10 are formed. The source regions extend through the epitaxial layer 70b to contact the highly doped semiconductor substrate layer of the first conductivity type 70a. Also, shallow trench isolation and deep trench isolation regions (not shown) may be formed.

Subsequently, the gate oxide 26 is deposited and patterned.

Then, the gate electrodes 14 are formed.

Next, the drain region 12 is formed intermediate the gate electrodes by means of ion implantation while using a suitable mask.

Then, a first dielectric layer 52 is deposited over at least the drain region 12. Subsequently, the first dielectric layer 52 is patterned to create a contact opening 51 at the location where the drain contact region 16 is to be created. Note that spacers (not shown) may be formed at the gate electrodes prior to patterning the first dielectric layer 52.

After creation of the contact opening 51 in the first dielectric layer 52, a poly-Si drain contact layer is deposited and patterned to form a poly-Si body 80 in the contact opening 51 in the first dielectric layer 52. The poly-Si drain contact layer as deposited comprises a dopant element of the second conductivity type. The thickness of the poly-Si drain contact layer as deposited is about 300 nm for a width of the contact opening 51 in the first dielectric layer 52 of about 400 nm.

In an embodiment, the poly-Si body 80 can be shaped with a portion extending laterally over the first dielectric layer. For example, the width of the extending portion of the poly-Si body is about 800 nm.

After patterning the poly-Si drain contact layer 80, a heat treatment is carried out to have diffusion of the dopant element of the second conductivity type from the poly-Si body into the drain region, in the contact opening where the patterned poly-Si drain contact layer 80 is in contact with the drain region 15. For example, the heat treatment relates to so-called rapid thermal processing which comprises an annealing step at high temperature during a short time (e.g. a temperature in a range from 1000 to 1100 ° C., during an annealing time between about 15 and about 30 s). Due to the out-diffusion of dopant from the patterned poly-Si drain contact layer to the drain region, a doped area with a relatively high level (n+) of the dopant element of the second conductivity type is formed in the drain region 15 as the drain contact region 16. It is noted that at the annealing temperature the outdiffusion rate of the dopant element from the poly-Si is faster than the diffusion rate of the dopant element in the drain region of the epitaxial layer 70b. The difference of the diffusion rates allows the creation of the drain contact region 16 with a relatively high level of dopant element in comparison to the remainder of the drain region, i.e., the drain extension region 15. Additionally or alternatively, a low dope implantation in the contact opening before poly-Si deposition may be done to create at least a portion of the doped area.

Next, in the top portion of the poly-Si body 80, an upper silicide layer 86 is formed by depositing a metal on the poly-Si and a subsequent annealing step (and removal of the unreacted metal). The thickness of the metal as deposited depends on the desired thickness of the upper silicide layer 86. Silicide formation (silicidation) per se is known to the person skilled in the art. Alternatively, the silicidiation process may be carried out so as to create a substantially completely silicided poly layer 80 which is arranged intermediate the drain contact region and the drain contact.

Then, the drain contact 20 is formed in a manner known in the art. In a next process the dielectric layer 50 is deposited. In the dielectric layer 50, the at least one metallisation level comprising at least one intermediate metal layer 30, 34, 38 and at least one inter-metal contact 32, 36, 40 is created. Finally, the top metal layer 22 is formed by deposition of metal followed by a patterning process. The person skilled in the art will appreciate that a liner 24 may be formed between the dielectric 50 and the top metal layer 22.

Also, the person skilled in the art will appreciate that the formation of shields 60 adjacent to the gate electrodes 14 can be done intermediate the processings steps mentioned above.

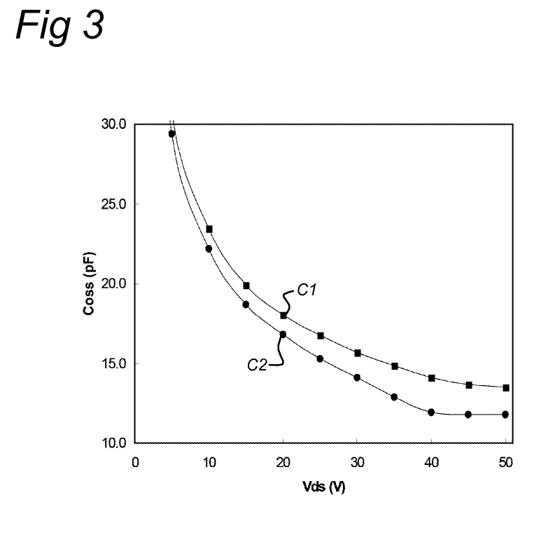

FIG. 3 shows a comparison of an output capacitance (drain-source) of an LDMOS transistor according to an embodiment and an LDMOS transistor of the prior art.

In FIG. 3 the output capacitance of the prior art LDMOS transistor and the LDMOS transistor according to the present invention is shown as a function of a drain-source voltage (Vds). The output capacitance behaviour of the LDMOS transistor of the prior art is shown by a curve C1. The output capacitance of the LDMOS transistor according to the present invention is shown by a curve C2. From the curves C1 and C2 it can be derived that the LDMOS transistor according to the present invention has a lower output capacitance than the LDMOS transistor from the prior art. The difference at a given drain-source voltage is about 10% at Vds=about 30 V.

Although specific embodiments of the invention have been described, it should be understood that the embodiments are not intended to limit the invention. The invention may embody any further alternative, modification or equivalent, only limited by the scope of the appended claims.

1. An LDMOS transistor on a substrate of a first conductivity type, comprising a source region and a drain region;
the source and drain regions being of a second conductivity type opposite to the first conductivity type and being mutually connected through a channel region in the substrate over which a gate electrode extends;
the drain region comprising a drain contact region and a drain extension region which extends from the channel region towards the drain contact region, the drain contact region being electrically connected to a top metal layer by a drain contact;
a poly-Si drain contact layer being arranged as a first contact material in between the drain contact region and the drain contact and in a contact opening of a first dielectric layer being deposited on the surface of the drain region, the poly-Si drain contact layer comprising a dopant element of the second conductivity type.

2. LDMOS transistor according to claim 1, wherein the poly-Si drain contact layer comprises a lower poly-Si layer and an upper silicide layer, the lower poly-Si layer being in contact with the drain contact region, the upper silicide layer being in contact with the drain contact.

3. LDMOS transistor according to claim 1, wherein the poly-Si drain contact layer is a silicided poly layer, arranged intermediate the drain contact region and the drain contact.

4. LDMOS transistor according to claim 1, wherein the poly-Si drain contact layer has an extending portion which extends over the first dielectric layer.

5. LDMOS transistor according to claim 4, wherein the extending portion of the poly-Si drain contact layer over the first dielectric layer is arranged as a field plate adapted in use for tailoring an electric field at an edge of the drain contact region.

6. LDMOS transistor according to claim 1, wherein the drain contact region has a high level of the dopant element of the second conductivity type and the drain extension region has a relatively lower level of the dopant element of the second conductivity type in comparison to the drain contact region.

7. LDMOS transistor according to claim 1, wherein the first conductivity type is p-type and the second conductivity type is n-type or vice-versa.

8. Semiconductor device comprising at least one LDMOS transistor in accordance with claim 1.

9. Method of manufacturing an LDMOS transistor comprising:
providing a substrate of a first conductivity type;
forming in the substrate a source region and a drain region, the source and drain regions being of a second conductivity type opposite to the first conductivity type and being mutually connected through a channel region in the substrate;
depositing a first dielectric layer over at least the drain region;
patterning the first dielectric layer to create a contact opening at a location of the drain region where a drain contact region is to be created;
depositing and subsequently patterning a poly-Si layer to form a poly-Si drain contact layer in the contact opening in the first dielectric layer as a first contact material on the drain contact region, the poly-Si drain contact layer comprising a dopant element of the second conductivity type.

10. Method according to claim 9, the method further comprising:
annealing the poly-Si drain contact layer so as to have diffusion of the dopant element of the second conductivity type from the poly-Si drain contact layer into the drain contact region.
